(19) United States
(12) Patent Application Publication
(10) Pub. No.: US 2012/0110411 A1
(43) Pub. Date: May 3, 2012

(54) Content Addressable Memory (CAM) Parity And Error Correction Code (ECC) Protection

(75) Inventors: Wing Cheung, Fremont, CA (US); Joseph Juh-En Cheng, Palo Alto, CA (US); John Michael Terry, San Jose, CA (US)

(73) Assignee: Brocade Communications Systems, Inc., San Jose, CA (US)

(21) Appl. No.: 12/916,384

(22) Filed: Oct. 29, 2010

(51) Int. Cl. G11C 29/52; H03M 13/29; H03M 13/05; G11C 15/00; G06F 11/10

(52) U.S. Cl. 714/758; 365/49.1; 365/49.17; 714/763; 714/807; 714/E11.034

(57) ABSTRACT

A memory system including a content addressable memory (CAM) array and a non-CAM array. The non-CAM array, which may share word lines with the CAM array, stores one or more error detection bits associated with each row of the CAM array. A state machine reads entries of the CAM array and corresponding error detection bits of the non-CAM array during idle cycles of the CAM array. Error detection logic identifies errors in the entries read from CAM array (using the retrieved error detection bits). If these errors are correctable, the error detection logic corrects the entry, and writes the corrected entry back to the CAM array (an updated set of error detection bits are also written to the non-CAM array). If these errors are not correctable, an interrupt is generated, which causes correct data to be retrieved from a shadow copy of the CAM array.

### FIELD OF THE INVENTION

The present invention relates to content addressable memory (CAM). More specifically, exemplary embodiments of the present invention relate to methods and structures for improving the accuracy of data stored by a CAM, among other aspects.

### RELATED ART

Many commercial applications are extremely sensitive to errors in data stored in an associated memory system. In particular, undetected errors in a memory system that implements a routing function in a networking application can mask data corruption and/or security holes. Note that the routing function in a networking application is typically implemented by an associative memory system, such as a binary or ternary CAM system.

Many types of memory systems have some type of available data integrity protection. For example, static random access memory (SRAM) and dynamic random access memory (DRAM) systems may include parity check logic or error detection/correction logic that detects/corrects errors as data is read from the memory system. However, due to the nature of conventional binary/ternary CAM systems, data integrity protection has not been applied to these memory systems. More specifically, because all entries of a CAM system are simultaneously accessed during a search operation, data integrity protection logic would have to be added to every row of the CAM system in order to provide protection while the CAM system is implementing search operations. Moreover, the time required to correct any detected errors would undesirably increase the cycle time of the CAM system. Adding data integrity protection to a CAM system has therefore been prohibitively expensive in terms of additional circuitry required and deterioration in performance. For these reasons, data integrity protection has not been added to CAM systems.

It would therefore be desirable to have methods and structures for implementing data integrity protection in binary/ternary CAM systems.

### SUMMARY

Accordingly, embodiments of the present invention provide an improved memory system that includes, among other things, a content addressable memory (CAM) array, which includes a plurality of binary or ternary CAM cells, and an associated non-CAM array, which includes a plurality of non-CAM cells. In accordance with one embodiment, the CAM array shares word lines with the non-CAM array, such that data can be simultaneously written to (or read from) the CAM array and the non-CAM array. The non-CAM array stores one or more error detection bits, which are derived from associated entries of the CAM array. In one embodiment, the non-CAM array stores one or more error detection bits (i.e., parity bits) for each row of the CAM array. In another embodiment, the non-CAM array stores a plurality of error detection bits (i.e., an error correction code) for each row of the CAM array.

The access control logic of the CAM array and the non-CAM array includes a background scan state machine, which reads the entries of the CAM array and the corresponding error detection bits from the non-CAM array during idle cycles of the CAM array. Error detection logic (e.g., parity check logic or error correction logic) identifies any errors in an entry read from CAM array, using the retrieved error detection bits. If no errors are detected, the background scan state machine proceeds to the next entry of the CAM array.

However, if an error is detected, and is correctable, then the error detection logic corrects the associated entry, and causes the background scan state machine to write the corrected entry back to the CAM array. At the same time, an updated set of error detection bits is generated in response to the corrected entry, and this updated set of error detection bits is written to the non-CAM array.

If an error is detected, but the error is not correctable, then the error detection logic causes the background scan state machine to generate an interrupt. This interrupt causes a corrected entry to be retrieved from a shadow copy of the CAM array. This corrected entry is then written back to the CAM array. At the same time, an updated set of error detection bits is generated in response to the corrected entry, and this updated set of error detection bits is written to the non-CAM array.

In the foregoing manner, data integrity protection is advantageously provided to CAM array, without requiring excessive additional logic.

In one embodiment, the structures and methods described herein may be used in, for example, a network switch, where one or more CAMs are used in association with packet processing.

The present invention will be more fully understood in view of the following description and drawings.

### BRIEF DESCRIPTION OF THE DRAWINGS

FIG. 1 is a block diagram of a memory system that includes a CAM array having parity protection in accordance with one embodiment of the present invention.

FIG. 2 is a block diagram of a memory system that includes a CAM array having parity protection in accordance with an alternate embodiment of the present invention.

FIG. 3 is a block diagram of a non-CAM array that stores a plurality of parity bits in accordance with one variation of the present invention.

FIG. 4 is a block diagram of a memory system that includes a CAM array having error correction and detection protection in accordance with another embodiment of the present invention.

FIG. 5 is a block diagram of a CAM array and an associated non-CAM array in accordance with an alternate embodiment of the present invention.

FIG. 6 is a block diagram of a system including a network switch that implements the memory system of the present invention.

### DETAILED DESCRIPTION

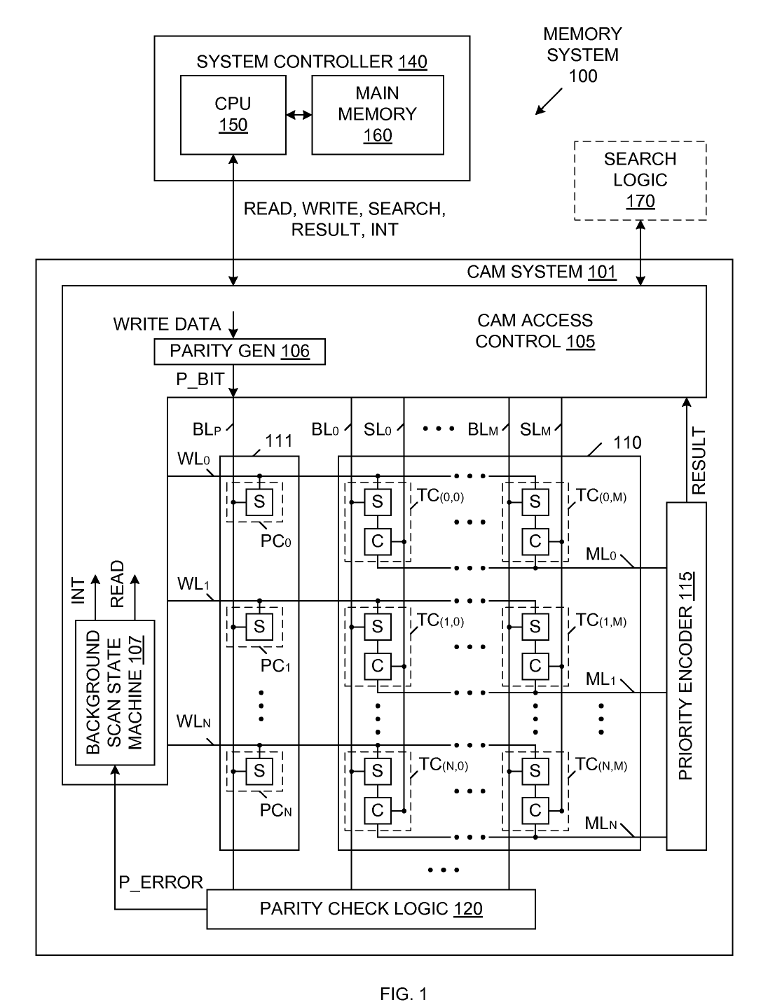

FIG. 1 is a block diagram of a memory system 100 in accordance with one embodiment of the present invention. Memory system 100 can be implemented in many applications, including, for example, a packet switching (e.g., bridging or routing) application in a networking device. In such an application, network addresses or other data useful for packet processing may be stored within memory system 100.

Memory system 100 includes CAM system 101 and system controller 140. In one embodiment, CAM system 101 is fabricated on a single integrated circuit chip and system controller 140 is fabricated on another integrated circuit chip (although this is not necessary). System controller 140 includes processor (CPU) 150 and main memory 160. CAM system 101 includes CAM access control logic 105, CAM array 110, parity memory array 111, priority encoder 115, and parity check logic 120. CAM access control logic 105 includes parity generator 106 and background scan state machine 107. As described in more detail below, CAM access control logic 105 controls read, write and search accesses to CAM array 110 and parity memory array 111. CAM access control logic 105 also generates interrupt signals (INT), which are provided to system controller 140 when erroneous data is detected in CAM array 110.

CAM array 110 includes a plurality of CAM cells, which are arranged in N+1 rows and M+1 columns (wherein N and M are integers greater than or equal to one). The CAM cells in CAM array 110 can be binary or ternary CAM cells. In the illustrated embodiment, CAM array 100 includes ternary CAM (TCAM) cells TC_{(0, 0)} to TC_{(N, M)}. Note that each of the CAM cells includes storage logic, which is labeled with an ‘S’, and comparison logic, which is labeled with a ‘C’. In general, the storage logic S is the target of read and write operations, and stores the logic state of the CAM cell (e.g., match logic ‘0’, match logic ‘1’, match logic ‘1’ or ‘0’, and ‘never match’). Note that binary CAM cells store only match logic ‘0’ and match logic ‘1’ states. The storage logic S is coupled to a corresponding word line (WL) and a corresponding set of bit lines (BL). Thus, the storage logic S of rows 0 to N of CAM array 110 are coupled to corresponding word lines WL₀ to WL_{N}, respectively. Similarly, the storage logic S of columns 0 to M of CAM array 110 are coupled to corresponding bit line sets BL₀ to BL_{M}, respectively. Note that although a single line is shown to represent a set of bit lines in FIG. 1, it is understood that there is more than one physical bit line in a bit line set, depending on the particular structure of the storage logic S. For example, a binary CAM cell may have a bit line set that includes two physical bit lines, and a TCAM cell may have a bit line set that includes four physical bit lines.

In general, the comparison logic C of the TCAM cells performs comparison operations during search operations to CAM array 110. The comparison logic C is coupled to receive the logic state of the associated storage logic S. The comparison logic C is also coupled to a corresponding set of one or more search lines (SL) and a corresponding match line (ML). Thus, the comparison logic C of columns 0 to M of CAM array 110 are coupled to corresponding search line sets SL₀ to SL_{M}, respectively. Similarly, the comparison logic of rows 0 to N are coupled to corresponding match lines ML₀ to ML_{N}, respectively. Although a single line is shown to represent a set of search lines in FIG. 1, it is understood that there may be more than one physical search line in a search line set, depending on the particular structure of the comparison logic C. For example, a binary CAM cell may have a search line set that includes one physical search line, and a TCAM cell may have a search line set that includes two physical search lines.

Parity memory array 111 includes a column of non-CAM cells. As defined herein, a non-CAM cell includes storage logic S, but does not include functional comparison logic C (which is found in a CAM cell). Examples of non-CAM cells include (but are not limited to), static random access memory (SRAM) cells and dynamic random access memory (DRAM) cells. In the described embodiment, parity memory array 111 is implemented by SRAM cells. Note that the storage logic S implemented by parity memory array 111 may be of the same type, or of a different type than the storage logic S implemented by CAM array 110.

Note that in an alternate embodiment, a non-CAM cell may include comparison logic C which is non-functional (i.e., not coupled to the associated storage logic S or an associated match line ML). Such an embodiment may facilitate the fabrication of CAM array 110 and the adjacent parity memory array 111, because memory cells in both arrays 110 and 111 would have similar layouts.

Parity memory array 111 includes a non-CAM cell associated with each row of CAM array 110. More specifically, parity memory array 111 includes non-CAM cells PC₀ to PC_{N}, which are associated with rows 0 to N, respectively, of CAM array 110. As described in more detail below, each of the non-CAM cells PC₀-PC_{N} stores a parity bit associated with an entry stored in the corresponding row of CAM array 110. In the embodiment illustrated by FIG. 1, each of the non-CAM cells PC₀-PC_{N} shares a word line with the corresponding row of CAM array 110. Thus, non-CAM cells PC₀ to PC_{N} are coupled to word lines WL₀ to WL_{N}, respectively. Parity memory array 111 also includes a corresponding bit line set BL_{P}, which is coupled to the storage logic S of non-CAM cells PC₀-PC_{N}.

The operation of memory system 100 will now be described. Processor 150 initially specifies an entry to be written to one of the rows of CAM array 110. Processor 150 writes the entry to a location within main memory 160, and also issues a write command to CAM system 101, wherein the write command instructs CAM access control logic 105 to write the entry to a specified row of CAM array 110. Processor 150 associates the storage location within main memory 160 with the specified row of CAM array 110, such that main memory 160 effectively stores a shadow copy of the contents of CAM array 110. In the described examples, main memory 160 is implemented by a non-CAM array (e.g., DRAM), and may include data integrity protection, such as error detection and correction (EDC).

CAM access control logic 105 receives the write command from processor 150, and in response, transmits the associated write data (entry) to parity generator 106. In response, parity generator 106 generates a parity bit P_BIT that corresponds with the write data. CAM access control logic 105 also decodes the write address included in the write command, and in response, initiates a write access to the addressed row. More specifically, CAM access control logic 105 activates the word line of the addressed row, applies the write data to the bit line sets BL₀-BL_{M}, and applies the parity bit P_BIT to bit line set BL_{P}. As a result, the write data and the parity bit P_BIT are written to the addressed row of CAM array 110 and parity memory array 111. Additional write accesses may be performed by processor 150, thereby populating CAM array 110, parity memory array 111 and main memory 160 with entries.

Search logic 170, which is coupled to memory system 100, may subsequently initiate search operations to CAM system 101. More specifically, search logic 170 transmits a search command (which includes search data) to CAM access control logic 105. In response, CAM access control logic 105 initiates a search access to CAM array 110 in a manner known to those of ordinary skill in the art. In general, the match lines ML₀-ML_{N} are pre-charged and the search data is applied to the search line sets SL₀-SL_{M}. Match lines having a predetermined voltage after application of the search data are deemed to represent a match with the search data. Priority encoder 115 determines which of the match lines represents a highest priority match, and returns a corresponding address (RESULT) to search logic 170 (via CAM access control logic 105).

In accordance with the present invention, background scan state machine 107 identifies idle cycles during which search logic 170 and system controller 140 are not accessing CAM system 101. During each idle cycle, background scan state machine 107 initiates a read access to a row of CAM array 110 (and parity memory array 111). During successive idle cycles, background scan state machine 107 initiates read accesses to successive rows of CAM array 110 and parity memory array 111, such that the rows of these arrays 110/111 are read in a cyclical manner. To initiate a read access, background scan state machine 107 activates the word line (WL) of the associated row. In response, the data stored in the memory cells of the associated row are read out on bit line sets BL₀-BL_{M} and BL_{P}, and are provided to parity check logic 120. Parity check logic 120 generates a parity bit in response to the data read out on bit line sets BL₀-BL_{M}, and compares this parity bit with the parity bit read out on bit line set BL_{P}. If parity check logic 120 does not detect a match, an error exists in the data read from CAM array 110. Under these conditions, parity check logic 120 activates an error signal (P_ERROR), which is provided to background scan state machine 107. In response, background scan state machine 107 generates an interrupt (INT), which is provided to processor 150. This interrupt identifies the row of CAM array 110 that includes the erroneous data. Using this information, processor 150 retrieves the non-erroneous data that should be stored in the identified row from the shadow copy maintained in main memory 160. Processor 150 then initiates a write access to CAM system 101, whereby the correct data is written to the identified row of CAM array 110 (and an associated parity bit is generated and written to parity memory array 111).

If parity check logic 120 determines that the parity bit generated in response to the data read from CAM array 110 matches the parity bit received on bit line set BL_{P}, then parity check logic 120 does not activate the error signal P_ERROR. In response, background scan state machine 107 initiates a read access to the next row of CAM array 110 (and parity memory array 111) during the next identified idle cycle.

In the foregoing manner, data integrity protection is advantageously provided to the entries of CAM array 110, without requiring excessive error correction logic within CAM system 100. Moreover, because the data integrity protection is only implemented during idle cycles of the system controller/search logic, the data integrity protection does not lengthen the cycle time of memory system 100.

Although parity memory array 111 has been described as having non-CAM cells in the above-described embodiments, it is understood that parity memory array 111 could be implemented with CAM cells in an alternate embodiment. However, this embodiment may undesirably exhibit an increased layout area (because memory cells PC₀-PC_{N} would be implemented by relatively large CAM cells), and an increased access time (because a parity bit would have to be generated and applied to parity memory array 111 during each search access), and an increased power requirement (because parity memory array 111 would have to be accessed during each search access).

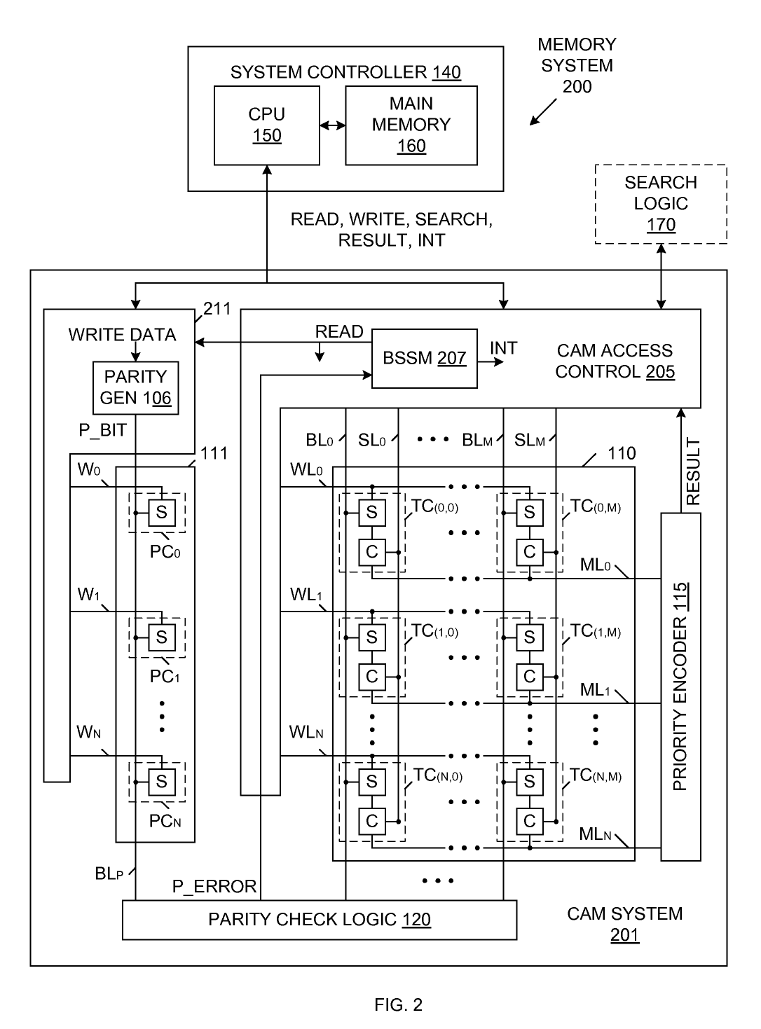

FIG. 2 is a block diagram of a memory system 200 in accordance with an alternate embodiment of the present invention. Memory system 200 includes CAM system 201, wherein the CAM array 110 is separate from the parity memory array 111 (i.e., do not share common word lines). Similar elements in memory systems 100 and 200 are labeled with similar reference numbers. Thus, memory system 200 includes system controller 140, parity bit generator 106, CAM array 110, parity memory array 111, priority encoder 115 and parity check logic 120, which have been described above in connection with FIG. 1. In addition, memory system 200 includes CAM access control logic 205 and parity memory access control logic 211. CAM access control logic 205 controls read, write and search accesses to CAM array 110 in the manner described above in connection with FIG. 1. Parity memory access control logic 211 controls read and write accesses to parity memory array 111. CAM system 201 physically separates the CAM array 110 and the parity memory array 111, such that each of these memory arrays has its own access control logic and its own word lines. That is, parity memory access control logic 211 accesses memory cells PC₀ to PC_{N} by dedicated word lines W₀ to W_{N}, respectively.

Both CAM access control logic 205 and parity memory access control logic 211 receive the write commands issued by processor 150. In response, CAM access control logic 205 writes the associated write data to the addressed row of CAM array 110 in the manner described above in connection with FIG. 1. Within parity memory access control logic 211, parity bit generator 106 generates the parity bit P_BIT in response to the received write data. Parity memory access control logic 211 causes the parity bit P_BIT to be written to the addressed row of parity memory array 111 (note that a write access will address the same rows of arrays 110 and 111.)

CAM access control logic 205 includes a background scan state machine 207, which is similar to background scan state machine 107 (FIG. 1). Thus, background scan state machine 207 initiates read accesses to CAM array 110 and parity memory array 111 during detected idle cycles of CAM system 201. Note that each of the read accesses address corresponding rows in arrays 110 and 111. Parity check logic 120 operates in the manner described above in connection with FIG. 1 to generate the error signal (P_ERROR), which is provided to background scan state machine 207. Upon receiving an activated error signal, background scan state machine 207 generates an interrupt (INT) to processor 150, which responds by retrieving the shadow copy of the erroneous data from main memory 160, and issuing a write command to write the correct data back to CAM array 110. Note that parity generator 106 generates a new parity bit P_BIT, which is written to parity memory array 111 during this write operation.

In one embodiment, all of the elements of CAM system 201 are fabricated on a single integrated circuit chip. In an alternate embodiment, parity memory array 111 and parity memory access control logic 211 are fabricated on a separate integrated circuit chip than the other elements of CAM system 201.

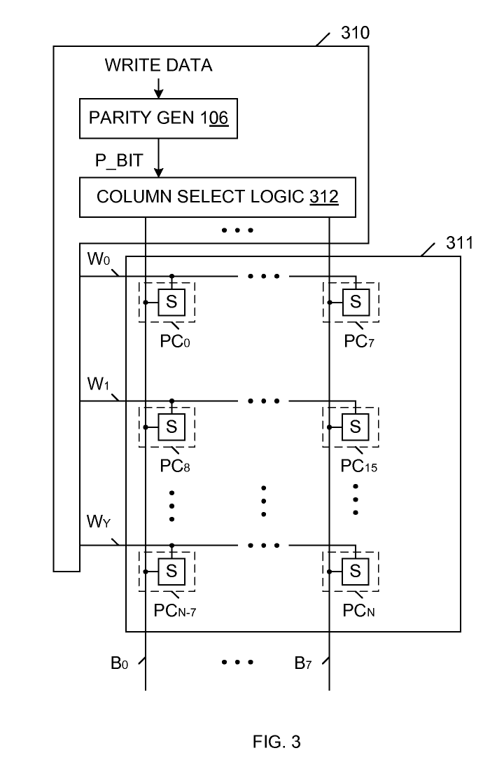

FIG. 3 is a block diagram of parity memory access control logic 310 and parity memory array 311 in accordance with one variation of the present embodiment. In this embodiment, parity memory access control logic 310 and parity memory array 311 replace parity memory access control logic 211 and parity memory array 111 in memory system 200 (FIG. 2). In this variation, each row of parity memory array 311 includes a plurality of non-CAM cells. In the illustrated example, each row of parity memory array 311 includes eight non-CAM cells. However, it is understood that each row of parity memory array 311 can include other numbers of parity memory cells in other embodiments. Parity memory array 311 includes Y+1 rows (i.e., word lines W₀ to W_{Y}), wherein Y is less than N. Parity memory array 311 also includes 8 columns (i.e., bit lines B₀-B₇). Like parity memory array 111, parity memory array 311 includes N+1 parity memory cells PC₀-PC_{N}, wherein each of the parity memory cells is associated with a corresponding row of CAM array 110.

Parity memory access control logic 310 includes column select logic 312, which routes the parity bit generated by parity bit generator 106 to one of the bit lines B₀-B₇ of parity memory array 311, depending on which row within CAM array 110 is being written. For example, the parity bit associated with row 0 (WL₀) of CAM array 110 is routed to bit line B₀, and the parity bit associated with row 7 (WL₇) of CAM array 110 is routed to bit line B₇. Parity memory access control logic 310 also activates the word lines W₀-W_{Y} in response to which row within CAM array 110 is being written. For example, parity memory access control logic 310 activates word line W₀ when any one of the rows WL₀-WL₇ of CAM array 110 is being written. The embodiment of FIG. 3 advantageously reduces the number of word lines required by the parity memory array.

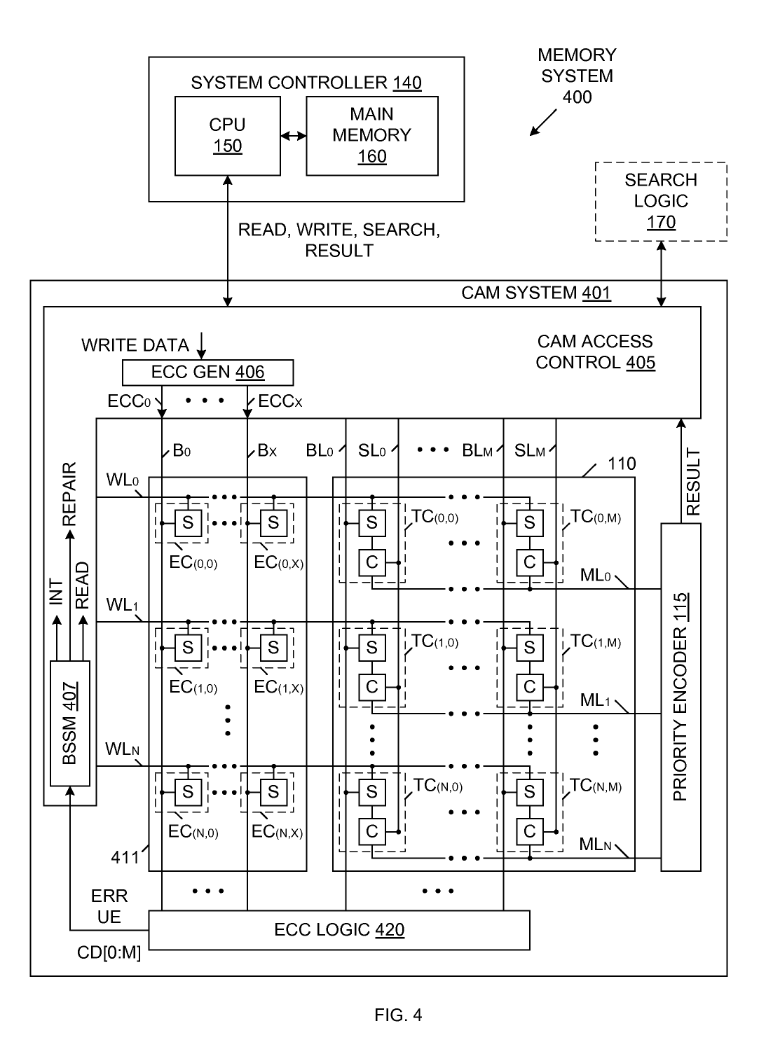

FIG. 4 is a block diagram of a memory system 400 in accordance with another embodiment of the present invention. As described in more detail below, this embodiment replaces the single parity bit implemented by memory system 100 with a plurality of error correction code (ECC) bits, which enable the detection and correction of erroneous data stored in CAM array 110.

Similar elements in memory systems 100 and 400 are labeled with similar reference numbers. Thus, memory system 400 includes system controller 140 (which includes processor 150 and main memory 160). Memory system 400 also includes a CAM system 401 that includes CAM array 110 and priority encoder 115, which have been described above in connection with FIG. 1. Memory system 400 replaces the parity bit generator 106 of memory system 100 with an error correction code (ECC) generator 406. In addition, memory system 400 replaces the parity memory array 111 of memory system 100 with an ECC memory array 411. ECC memory array 411 includes N+1 rows and X+1 columns of memory cells, wherein X is an integer greater than or equal to one. Thus, ECC memory array 411 includes memory cells EC_{(0, 0)} to EC_{(N, X)}, which are arranged as illustrated. Memory system 400 also replaces the parity check logic 120 of memory system 100 with ECC logic 420. Finally, memory system 400 replaces the background scan state machine 107 of memory system with background scan state machine 407.

Memory system 400 operates as follows. Processor 150 initially specifies an entry to be written to one of the rows of CAM array 110. Processor 150 writes the entry to a location within main memory 160, and also issues a write command to CAM system 401, wherein the write command instructs CAM access control logic 405 to write the entry to a specified row of CAM array 110. As described above in connection with FIG. 1, processor 150 associates the storage location within main memory 160 with the specified row of CAM array 110, such that main memory 160 effectively stores a shadow copy of the contents of CAM array 110.

CAM access control logic 405 receives the write command from processor 150, and in response, transmits the associated write data (entry) to ECC generator 406. In response, parity generator 106 generates an ECC value, which includes a plurality of ECC bits ECC₀ to ECC (wherein X is an integer greater than or equal to 1). These ECC bits ECC₀-ECC_{X} are provided to ECC memory array 411 on corresponding bit lines sets B₀-B_{X}.

CAM access control logic 405 also decodes the write address included in the write command, and in response, initiates a write access to the addressed row. More specifically, CAM access control logic 405 activates the word line of the addressed row, applies the write data to the bit line sets BL₀-BL_{M}, and applies the ECC bits ECC₀ to ECC to bit line sets B₀ to B_{X}, respectively. As a result, the write data and the ECC bits ECC₀-ECC_{X} are written to the addressed row of CAM array 110 and ECC memory array 411. Additional write accesses may be performed by processor 150, thereby populating CAM array 110, ECC memory array 411 and main memory 160 with entries.

Search logic 170 may subsequently initiate search operations to CAM system 401. More specifically, search logic 170 transmits a search command (which includes search data) to CAM access control logic 405. In response, CAM access control logic 405 initiates a search access to CAM array 110 in the manner described above in connection with FIG. 1. Note that ECC memory array 411 is not accessed during these search operations.

In accordance with the present embodiment, background scan state machine 407 identifies idle cycles during which search logic 170 is not accessing CAM system 401. During each idle cycle, background scan state machine 407 initiates a read access to a row of CAM array 110 (and ECC memory array 411). During successive idle cycles, background scan state machine 407 initiates read accesses to successive rows of CAM array 110 and ECC memory array 411, such that the rows of these arrays 110/411 are read in a cyclical manner. To initiate a read access, background scan state machine 407 activates the word line (WL) of the associated row. In response, the data stored in the memory cells of the associated row are read out on bit line sets BL₀-BL_{M} and B₀-B_{X}, and are provided to ECC logic 420. ECC logic 420 generates an ECC value in response to the data read out on bit line sets BL₀-BL_{M}, and compares this ECC value with the ECC value ECC₀-ECC_{X} read out on bit line sets B₀-B_{X}. Using well known ECC techniques, ECC logic 420 uses the results of this comparison to determine whether any errors exist in the data read out on bit line sets BL₀-BL_{M}. If one or more errors are detected in the read data, ECC logic 420 activates an error signal (ERR). Note that different ECC algorithms are capable of detecting and correcting different number of errors in the read data. In the described examples, the ECC algorithm implemented by ECC logic 420 is capable of detecting and correcting up to Z erroneous bits in the read data, wherein Z is an integer greater than or equal to one. If more than Z errors are detected, ECC logic 420 activates an uncorrectable error signal (UE) to indicate that errors in the read data are uncorrectable. If at least one and no more than Z errors are detected, ECC logic 420 identifies the bit location of each of error, and corrects each error, thereby generated a corrected data value CD[0:M].

If ECC logic 420 does not detect an error in the read data, then ECC logic 420 reports this condition to background scan state machine 407 by maintaining the error signal ERR and the uncorrectable error signal UE in de-activated logic states. In response, background scan state machine 407 continues the process by reading the next row address of arrays 110/411 during the next detected idle cycle.

If a correctable number of errors are detected, ECC logic 420 generates a corrected data value CD[M:0] as described above. ECC logic 420 also activates the error signal ERR and de-activates the uncorrectable error signal UE. Background scan state machine 407 receives these signals, and in response, initiates a repair write operation. To implement the repair write operation, background scan state machine 407 provides the corrected data value CD[0:M] to ECC generator 406, which generates a corresponding ECC value ECC₀-ECC_{X}, which is provided to bit line sets B₀-B_{X}. Background scan state machine 407 also applies the corrected data value CD[0:M] to the bit line sets BL₀-BL_{M}, and activates the word line (WL) associated with the original read access. As a result, the corrected data value CD[0:M] is written to the appropriate row of CAM array 110 (thereby overwriting the erroneous data previously detected in this row) and the associated ECC value is written to the corresponding row of ECC memory array 411.

If an uncorrectable number of errors are detected, ECC logic 420 activates both the error signal ERR and the uncorrectable error signal UE. In response, background scan state machine 407 generates an interrupt signal INT, which is provided to processor 150. This interrupt identifies the row of CAM array 110 that includes the erroneous data. Using this information, processor 150 retrieves the non-erroneous data that should be stored in the identified row from the shadow copy maintained in main memory 160. Processor 150 then initiates a write access to CAM system 401, whereby the correct data is written to the identified row of CAM array 110 (and the corresponding ECC value is generated by ECC generator 406, and is written to the corresponding row of ECC memory array 411).

Because CAM system 401 corrects most erroneous data internally (i.e., without having to interrupt system processor 140), most errors can be corrected quickly. It is expected that CAM system 401 will rarely have to interrupt system processor 140 to correct erroneous data, thereby allowing system processor 140 to perform other processing tasks. CAM system 401 advantageously uses a single ECC logic block 420, which is shared by all rows of CAM array 110, thereby providing an efficient manner of implementing error detection and correction.

In accordance with an alternate embodiment of the present invention, CAM system 401 can be modified, such that CAM memory 110 and ECC memory 411 are separate memories (i.e., do not share the same word lines). This alternate embodiment may be realized by following the teachings set forth above in connection with FIG. 2.

In accordance with yet another embodiment, ECC memory 411 can be modified such that each row of this ECC memory stores a plurality of ECC values, thereby allowing the number of rows (word lines) of this ECC memory to be reduced, in the manner described above in connection with FIG. 3.

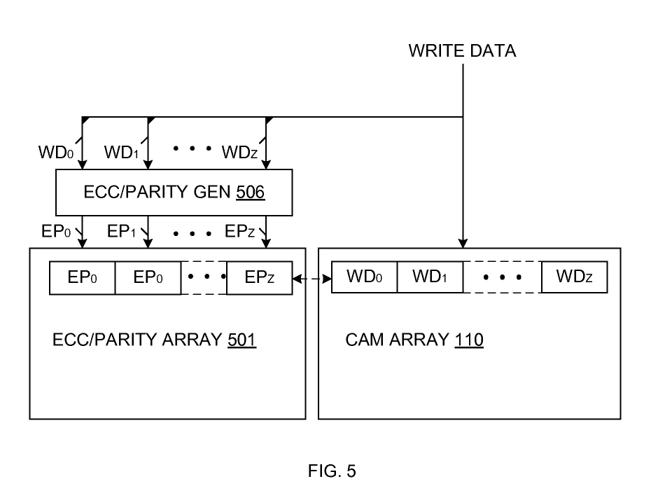

FIG. 5 is a block diagram illustrating another embodiment of the present invention, wherein each write data value is logically divided into a plurality of write data sections WD₀-WD_{Z}. In the illustrated example, each write data value is logically divided into Z+1 write data sections, wherein each of the write data sections includes a plurality of bits. An ECC (or parity) generator 506 receives each of the write data sections WD₀-WD_{Z}, and in response, generates Z+1 corresponding ECC (or parity) values EP₀-EP_{Z}, wherein each ECC/parity value is generated entirely in response to the corresponding write data section. The ECC/parity values generated by ECC/parity generator 506 are written to non-CAM cells of an ECC/parity memory array 501, and are associated with the corresponding write data value written to CAM array 110 (i.e., in one of the manners described above).

In a particular example, each row of CAM array 110 includes 256 bits (i.e., M=255), and Z is set equal to 7. In this case, the write data value can be represented as WD[255:0], and the eight write data sections WD₀-WD₇ can be represented as WD[255:224], WD[223:192], WD[191:160], WD[159:128], WD[127:96], WD[95:64], WD[63:32] and WD[31:0]. In this case, ECC/parity generator 506 generates ECC/parity values EP₀-EP₇ in response to the write data sections WD₀-WD₇, respectively. Note that each ECC/parity value EP_{A} provides data integrity protection to the corresponding write data section WD_{A} (wherein ‘A’ includes the integers from 0 to 7, inclusive).

During an idle cycle, the write data portions WD₀-WD_{Z} are read from the associated row of CAM array 110, and the ECC/parity values EP₀-EP_{Z} are read from the corresponding locations within ECC/parity memory array 501. Associated ECC/parity check logic receives these values (WD₀-WD_{Z} and EP₀-EP_{Z}) and performs ECC (or parity check) operations in the manner described above, wherein the each ECC/parity value EP_{A} is used to check/correct the integrity of the corresponding write data section WD_{A}. Logically dividing the write data into smaller write data portions, and providing data integrity protection to these smaller write data portions in the above described manner can advantageously provide for faster error detection/correction in the case of wide write data values. Note that the ECC/parity values EP₀-EP_{Z} can be stored in ECC/parity memory array 501 in any one of the manners described above in connection with FIGS. 1-4.

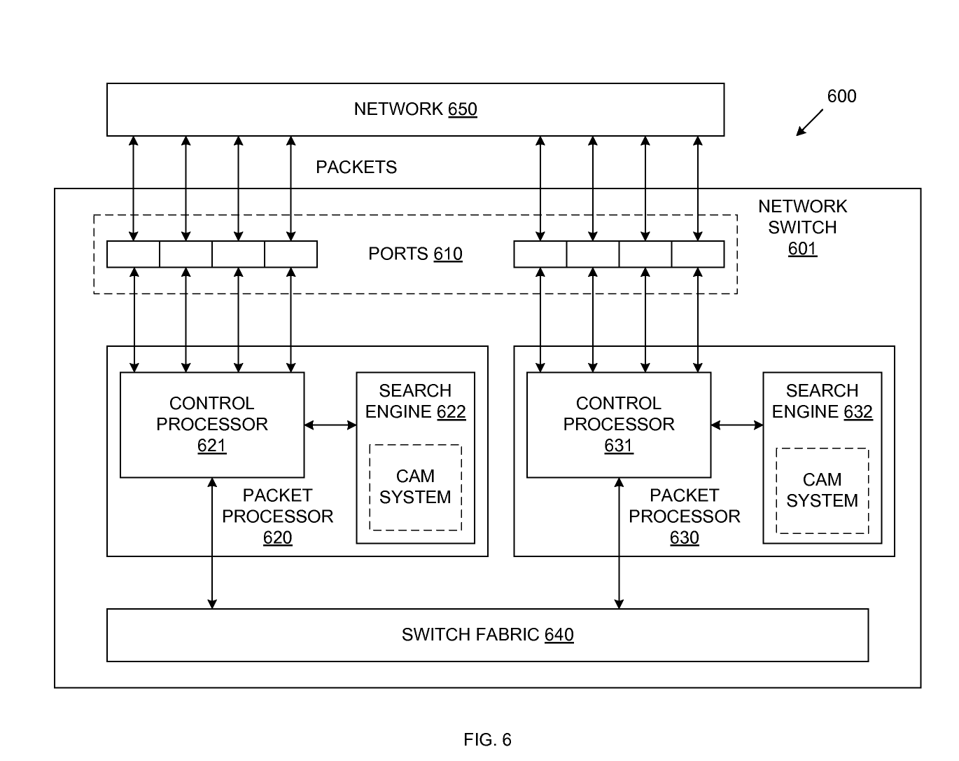

FIG. 6 is a block diagram of a system 600 that includes a network switch 601, in which the memory systems described above may be implemented. The term “switch” is used broadly, and may include any packet switching device in any kind of network. For instance, the switch may be part of a MAN, LAN or SAN. The switch may transmit Ethernet, ATM, Fibre Channel, or Fibre Channel over Ethernet packets.

In particular, FIG. 6 shows a switch 601, which includes a plurality of input/output ports 610 coupled to a network 650, e.g., Ethernet or Fibre Channel network. Switch 601 also includes packet processors 620 and 630 that receive receives packets from, and output packets to, the ports 610, directly or indirectly. Packet processors 620 and 630 include control processors 621 and 631, respectively, and search engines 622 and 632, respectively. In the described example, at least one of the search engines 622 and 632 implements a CAM system in accordance with one or more of the embodiments described above in connection with FIGS. 1-5. Thus, each of the search engines 622 and 632 includes a CAM system having a corresponding binary or ternary CAM memory array and a corresponding ECC or parity memory array. Search engines 622 and 632 are shown integrated within packet processors 620 and 630, but may be implemented in separate components in other embodiments. Each packet processor 620, 630 may be an ASIC or FPGA. Control processors 621 and 631 control read, write and search accesses to search engines 622 and 632, respectively, in the manner described above. In accordance with one embodiment, each of the control processors 621 and 631 implements the functionality of system controller 140 and/or search logic 170, as described above.

In operation, as an example, a packet received from network 650 on one of the ports 610 is provided to control processor 621 within packet processor 620. Control processor 621 provides the packet (or a portion thereof, such as the destination address and/or other header fields) to search engine 622, which processes this packet using information stored in this search engine 622. In particular, search engine 622 performs a search operation in accordance with any one of the various embodiments described above. Search engine 622 provides the search result to control processor 621. In response, control processor 621 uses the search result to address the associated packet for forwarding. Control processor 621 outputs the packet (which may include an internal header) to switching fabric 640. Switching fabric 640 routes the packet to one of the packet processors 620 or 630 in accordance with destination information and other information in the packet. The output packet processor 620 or 630 may further process the packet prior to outputting the packet to one of the ports 610, and from there out into the network 650. Although the present invention has been described in connection with various embodiments, it is understood that variations of these embodiments would be obvious to one of ordinary skill in the art. For example, although the embodiments described herein implement hardware state machines (107, 207, 407) to implement the background scanning function, it is understood that this function can alternately be implemented by software in other embodiments. Note however, that hardware scanning is desirable because it is typically much faster than software scanning. Thus, the present invention is limited only by the following claims.

We claim:

1. A memory system comprising:
a row of content addressable memory (CAM) cells; and
a first non-CAM cell associated with the row of CAM cells.

2. The memory system of claim 1, wherein the row of CAM cells stores an entry, and the first non-CAM cell stores an error detection bit derived from the entry.

3. The memory system of claim 2, wherein the error detection bit is a parity bit that represents a parity of the entry.

4. The memory system of claim 3, further comprising parity check logic coupled to the first non-CAM cell and the row of CAM cells.

5. The memory system of claim 3, further comprising means for generating an interrupt if the parity of the entry does not match the parity bit.

6. The memory system of claim 2, further comprising a parity generator for generating the error detection bit in response to the entry.

7. The memory system of claim 1, further comprising a word line, wherein the row of CAM cells and the first non-CAM cell share the word line.

8. The memory system of claim 1, further comprising a second non-CAM cell associated with the row of CAM cells.

9. The memory system of claim 8, wherein the row of CAM cells stores an entry, and the first and second non-CAM cells store an error correction code derived from the entry.

10. The memory system of claim 9, further comprising error correction logic coupled to the row of CAM cells and the first and second non-CAM cells.

11. The memory system of claim 10, wherein the error correction logic corrects errors in the entry in response to the error correction code, thereby creating a corrected entry, the memory system further comprising means for writing the corrected entry to the row of CAM cells.

12. The memory system of claim 9, further comprising an error correction code generator for generating the error correction code in response to the entry.

13. The memory system of claim 8, further comprising a word line, wherein the row of CAM cells and the first and second non-CAM cells share the word line.

14. A memory system comprising:
a content addressable memory (CAM) array that includes a plurality of CAM cells arranged in a plurality of rows and columns; and
a memory array that includes a plurality of non-CAM cells, each associated with a corresponding one of the rows of the CAM array, wherein each of the non-CAM cells stores an error detection bit that is derived from an entry of the corresponding one of the rows of the CAM array.

15. The memory system of claim 14, wherein the CAM array and the memory array are located on the same integrated circuit chip.

16. The memory system of claim 14, wherein the CAM array and the memory array share common word lines.

17. The memory array of claim 14, further comprising an access control circuit that implements search operations to the CAM array, the access control circuit including a state machine that simultaneously reads from the CAM array and the memory array when search operations are not being performed to the CAM array.

18. The memory array of claim 17, wherein the state machine reads successive entries from the CAM array and the memory array.

19. The memory system of claim 14, further comprising an error detection circuit coupled to receive an entry from a row of the CAM array and one or more error detection bits from the memory array.

20. A method comprising:
generating a first set of one or more error detection bits in response to a data value;
storing the data value in a row of a content addressable memory (CAM) array; and
storing the first set of one or more error detection bits in a location of non-CAM array, wherein the row of the CAM array is associated with the location of the non-CAM array.

21. The method of claim 20, further comprising maintaining a shadow copy of the CAM array in a main memory array.

22. The method of claim 20, further comprising activating a single word line to store both the data value in the row of the CAM array and the first set of one or more error detection bits in the location of the non-CAM array.

23. The method of claim 20, further comprising simultaneously storing the data value in the row of the CAM array and the first set of one or more error detection bits in the location of the non-CAM array.

24. The method of claim 20, further comprising simultaneously reading the data value from the row of the CAM array and the first set of one or more error detection bits from the location of the non-CAM array.

25. The method of claim 24, further comprising generating a second set of one or more error detection bits in response to the data value read from the row of the CAM array.

26. The method of claim 25, further comprising comparing the second set of one or more error detection bits with the first set of one or more error detection bits.

27. The method of claim 26, further comprising generating an interrupt if the second set of one or more error detection bits does not match the first set of one or more error detection bits.

28. The method of claim 27, further comprising retrieving a copy of the data value in response to the interrupt.

29. The method of claim 28, further comprising, generating a third set of one or more error detection bits in response to the copy of the data value.

30. The method of claim 29, further comprising:
writing the third set of one or more error detection bits to the location of the non-CAM array; and
writing the copy of the data value to the row of the CAM array.

31. The method of claim 26, further comprising correcting one or more errors in the data value read from the CAM array in response to the first and second sets of one or more error detection bits, thereby creating a corrected data value.

32. The method of claim 31, further comprising writing the corrected data value to the row of the CAM array.

33. The method of claim 32, further comprising:
generating a third set of one or more error detection bits in response to the corrected data value; and
writing the third set of one or more error detection bits to the location of the non-CAM array.

34. The method of claim 20, further comprising:
performing search operations to the CAM array; and
reading the data value from the row of the CAM array and simultaneously reading the first set of one or more error detection bits from the location of the non-CAM array when no search operations are performed to the CAM array.
